(19) United States
(12) Patent Application Publication
(10) Pub. No.: US 2023/0121635 A1
(43) Pub. Date: Apr. 20, 2023

(54) IMMERSION HEAT DISSIPATION STRUCTURE HAVING MACROSCOPIC FIN STRUCTURE AND IMMERSION HEAT DISSIPATION STRUCTURE HAVING FIN STRUCTURE

(71) Applicant: AMULAIRE THERMAL TECHNOLOGY, INC., New Taipei City (TW)

(72) Inventors: CHING-MING YANG, New Taipei City (TW); CHENG-SHU PENG, New Taipei City (TW); TZE-YANG YEH, New Taipei City (TW)

(21) Appl. No.: 17/500,951

(22) Filed: Oct. 14, 2021

(51) Int. Cl. F28F 3/06

(52) U.S. Cl. CPC F28F 3/06

(57) ABSTRACT

An immersion heat dissipation structure having a macroscopic fin structure and an immersion heat dissipation structure having a fin structure are provided. The immersion heat dissipation structure having a macroscopic fin structure includes a surface having at least two contact angles. At least one part of the surface has one of the at least two contact angles between an immersion cooling liquid that is greater than 90 degrees, and at least another part of the surface has another one of the at least two contact angles between the immersion cooling liquid that is from 0 degrees to 90 degrees.

### FIELD OF THE DISCLOSURE

The present disclosure relates to a heat dissipation structure, and more particularly to an immersion heat dissipation structure having a macroscopic fin structure and an immersion heat dissipation structure having a fin structure.

### BACKGROUND OF THE DISCLOSURE

An immersion cooling technology is performed by directly immersing heat-generating components (such as servers and disk arrays) in a non-electrically conductive cooling fluid, so that heat generated by operations of the heat-generating components can be removed by evaporation of the cooling fluid. However, how to dissipate heat more effectively through the immersion cooling technology is one of issues that need to be addressed in the related field.

### SUMMARY OF THE DISCLOSURE

In response to the above-referenced technical inadequacy, the present disclosure provides an immersion heat dissipation structure having a macroscopic fin structure and an immersion heat dissipation structure having a fin structure.

In one aspect, the present disclosure provides an immersion heat dissipation structure having a macroscopic fin structure which includes a surface having at least two contact angles. At least one part of the surface has one of the at least two contact angles between an immersion cooling liquid that is greater than 90 degrees, and at least another part of the surface has another one of the at least two contact angles between the immersion cooling liquid that is from 0 degrees to 90 degrees.

In certain embodiments, the macroscopic fin structure is a fin structure formed on the surface and the fin structure has a height of at least 100 μm from the surface.

In another aspect, the present disclosure provides an immersion heat dissipation structure having a fin structure which includes a heat dissipation base, at least one hydrophobic layer, and at least one fin. The at least one fin and the at least one hydrophobic layer are correspondingly formed on the heat dissipation base, and the at least one hydrophobic layer is formed on an area of the heat dissipation base other than an area where the at least one fin is arranged. A surface of the at least one hydrophobic layer has a contact angle between an immersion cooling liquid that is greater than 90 degrees.

In certain embodiments, the at least one hydrophobic layer is formed on the area of the heat dissipation base other than the area where the at least one fin is arranged by physical deposition, chemical deposition, or spraying, and the at least one fin is a pin fin, a plate fin, or a composite fin structure formed by a combination of the pin fin and the plate fin.

In still another aspect, the present disclosure provides an immersion heat dissipation structure having a fin structure, which includes a heat dissipation base, at least one hydrophilic layer, and at least one fin. The at least one fin is formed on the heat dissipation base, and the at least one hydrophilic layer is formed on the at least one fin. A surface of the at least one hydrophilic layer has a contact angle between an immersion cooling liquid that is from 0 degrees to 90 degrees. The at least one hydrophilic layer and the at least one fin are made of two materials that are different from each other, and the at least one hydrophilic layer and the heat dissipation base are made of two materials that are different from each other.

In certain embodiments, the at least one hydrophilic layer is formed on the at least one fin by immersion plating, and the at least one fin is a pin fin, a plate fin, or a composite fin structure formed by a combination of the pin fin and the plate fin.

In yet another aspect, the present disclosure provides an immersion heat dissipation structure having a fin structure, which includes a heat dissipation base, at least one hydrophobic layer, at least one hydrophilic layer, and at least one fin. The at least one fin is formed on the heat dissipation base, the at least one hydrophilic layer is formed on the at least one fin, and the at least one hydrophobic layer is formed on an area of the heat dissipation base other than an area where the at least one fin is arranged. A surface of the at least one hydrophobic layer has a contact angle between an immersion cooling liquid that is greater than 90 degrees, and a surface of the at least one hydrophilic layer has a contact angle between the immersion cooling liquid that is from 0 degrees to 90 degrees.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a heat dissipation structure according to a first embodiment of the present disclosure;

FIG. 2 is a schematic view of a contact angle of a part of a surface of the heat dissipation structure to an immersion cooling liquid of the present disclosure;

FIG. 3 is another schematic view of the contact angle of the part of the surface of the heat dissipation structure to the immersion cooling liquid of the present disclosure;

FIG. 4 is a schematic side view of a heat dissipation structure according to a second embodiment of the present disclosure;

FIG. 5 is a schematic side view of a heat dissipation structure according to a third embodiment of the present disclosure; and

FIG. 6 is a schematic side view of a heat dissipation structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

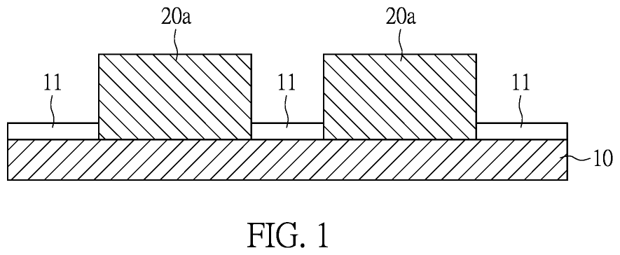

Reference is made to FIG. 1, in which a first embodiment of the present disclosure is shown, the first embodiment of the present disclosure provides an immersion heat dissipation structure having a macroscopic fin structure, which can be used to contact heat generating components. As shown in FIG. 1, the immersion heat dissipation structure having the macroscopic fin structure according to the first embodiment of the present disclosure (hereinafter being referred to as the immersion heat dissipation structure) includes a surface having at least two contact angles.

Further, in the present embodiment, the immersion heat dissipation structure can include a heat dissipation base 10 and one or more macroscopic fins 20a arranged on the heat dissipation base 10, and can be immersed in an immersion cooling liquid that has a two phase property (such as electronic fluorinated liquid). In addition, the heat dissipation base 10 and the macroscopic fin 20a can be integrally formed by metal injection molding (MIM). In the present embodiment, the macroscopic fin 20a refers to a fin structure formed on the surface and the fin structure has a height of at least 100 μm from the surface. Moreover, the macroscopic fin 20a can be a pin fin, a plate fin, or other similar composite fin structures.

It is worth mentioning that, in the immersion heat dissipation structure of the present embodiment, at least one part of the surface has a contact angle between the immersion cooling liquid that is greater than 90 degrees, and at least another part of the surface has a contact angle between the immersion cooling liquid that is from 0 degrees to 90 degrees.

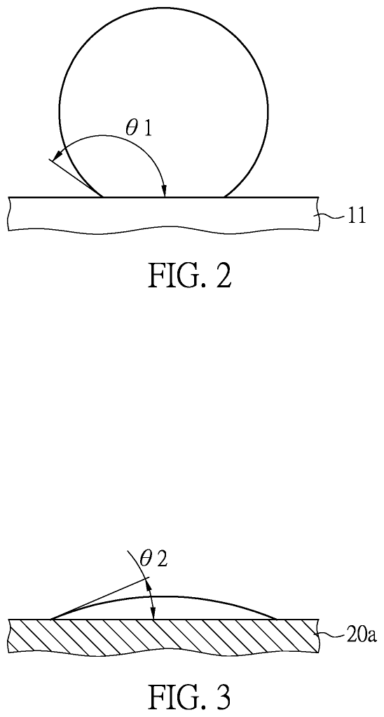

Further, in the present embodiment, at least one hydrophobic layer 11 is formed on a platform area on the surface of the heat dissipation base 10 other than an area where the macroscopic fin 20a is arranged, and a surface of the hydrophobic layer 11 has a contact angle θ1 between the immersion cooling liquid that is greater than 90 degrees (as shown in FIG. 2), so that the immersion heat dissipation structure of the present embodiment has the at least one part of the surface having the contact angle between the immersion cooling liquid that is greater than 90 degrees. Moreover, the macroscopic fin 20a of the present embodiment is a porous metal fin, and the surface of the macroscopic fin 20a has a contact angle θ2 between the immersion cooling liquid that is from 0 degrees to 90 degrees (as shown in FIG. 3), so that the immersion heat dissipation structure of the present embodiment has the at least another part of the surface having the contact angle between the immersion cooling liquid that is from 0 degrees to 90 degrees.

Therefore, in the present embodiment, the surface of the macroscopic fin 20a has a high critical heat flux (CHF) and a low number of nucleation sites of air bubbles since the contact angle of the surface of the macroscopic fin 20a between the immersion cooling liquid is from 0 degrees and 90 degrees, while the surface of the hydrophobic layer 11 formed on the platform area of the heat dissipation base 10 has a high number of nucleation sites of air bubbles and a low CHF since the contact angle of the surface of the hydrophobic layer 11 formed on the platform area of the heat dissipation base 10 between the immersion cooling liquid is greater than 90 degrees. While the high number of nucleation sites causes an increase of a heat transfer coefficient (HTC), the low CHF causes a conversion of nucleation boiling to film boiling to easily occur, such that a gas film is formed, thereby leading to formation of air thermal resistance. The macroscopic fin 20a is the main heat dissipation area, which has a large area with a certain number of pores and a certain number of nucleation blocks, thereby having a high HTC. Accordingly, the hydrophobic layer 11 is suitable to be formed on the platform area of the surface of the heat dissipation base 10 other than the area where the macroscopic fin 20a is disposed, so that even if air thermal resistance is caused by the conversion of nucleation boiling to film boiling, heat can be transferred through an area of the macroscopic fin 20a by thermal conduction.

Further, in the present embodiment, the hydrophobic layer 11 can be formed on the platform area of the heat dissipation base 10 by physical deposition, chemical deposition, or spraying, and a contact angle of a surface of a forming material to the immersion cooling liquid can be changed by adjusting the forming material that is used or by a microstructure of the surface of the forming material.

### Second Embodiment

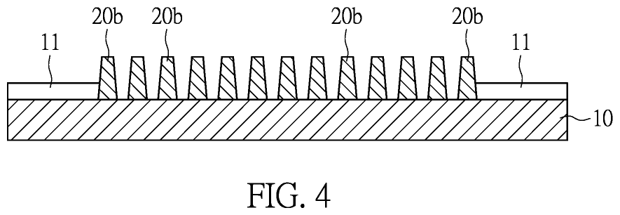

Reference is made to FIG. 4, in which a second embodiment of the present disclosure is shown. The second embodiment is substantially the same as the first embodiment, and provides an immersion heat dissipation structure having a fin structure, which includes a heat dissipation base 10, at least one hydrophobic layer 11, and at least one fin 20b. The at least one fin 20b and the at least one hydrophobic layer 11 are correspondingly formed on the heat dissipation base 10. In the present embodiment, the at least one fin 20b is made of a hydrophilic metal material, and can be a pin fin, a plate fin, or other similar composite fin structures. In addition, in the present embodiment, the at least one hydrophobic layer 11 is formed on an area of the heat dissipation base 10 other than the area where the at least one fin 20b is arranged, such as a peripheral area other than the area where the at least one fin 20b is arranged, and a surface of the at least one hydrophobic layer 11 has a contact angle between the immersion cooling liquid that is greater than 90 degrees.

### Third Embodiment

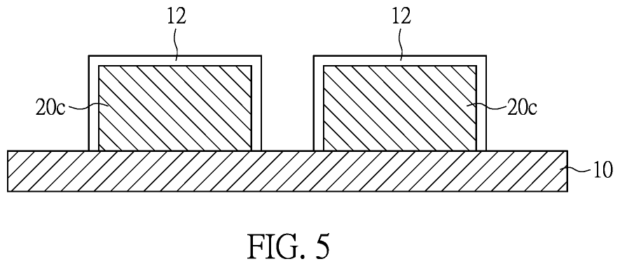

Reference is made to FIG. 5, in which a third embodiment of the present disclosure is shown. The third embodiment is substantially the same as the first embodiment, and provides an immersion heat dissipation structure having a fin structure, which includes a heat dissipation base 10, at least one hydrophilic layer 12, and at least one fin 20c. The at least one fin 20c is formed on the heat dissipation base 10, and the at least one hydrophilic layer 12 is formed on the at least one fin 20c. A surface of the at least one hydrophilic layer 12 has a contact angle between the immersion cooling liquid that is from 0 degrees to 90 degrees.

Further, in the present embodiment, the at least one hydrophilic layer 12 can be formed on the at least one fin 20c by immersion plating, and a contact angle of a surface of a forming material to the immersion cooling liquid can be modulated through the forming material that is used or a microstructure of the surface of the forming material. It is worth mentioning that, in the present embodiment, the at least one hydrophilic layer 12 and the at least one fin 20c are made of two materials that are different from each other, and the at least one hydrophilic 12 and the heat dissipation base 10 are made of two materials that are different from each other. That is to say, in the present embodiment, the at least one fin 20c and the heat dissipation base 10 can each be made of a non-hydrophilic material.

### Fourth Embodiment

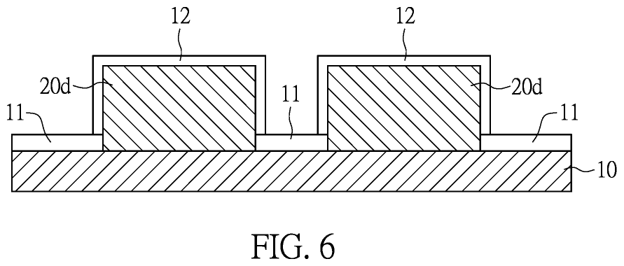

Reference is made to FIG. 6, in which a fourth embodiment of the present disclosure is shown. The fourth embodiment is substantially the same as the first embodiment, and provides an immersion heat dissipation structure having a fin structure, which includes a heat dissipation base 10, at least one hydrophobic layer 11, at least one hydrophilic layer 12, and at least one fin 20d. In the present embodiment, the at least one fin 20d is formed on the heat dissipation base 10, the at least one hydrophilic layer 12 is formed on the at least one fin 20d, and the at least one hydrophobic layer 11 is formed on an area of the heat dissipation base 10 other than the area where the at least one fin 20d is arranged. A surface of the at least one hydrophobic layer 11 has a contact angle between the immersion cooling liquid that is greater than 90 degrees, and a surface of the at least one hydrophilic layer 12 has a contact angle between the immersion cooling liquid that is from 0 degrees to 90 degrees.

In the present embodiment, the at least one hydrophobic layer 11 can be formed on the area of the heat dissipation base 10 other than the area where the at least one fin 20d is arranged by physical deposition, chemical deposition, or spraying, and the at least one hydrophilic layer 12 can be formed on the at least one fin 20d by immersion plating.

### Beneficial Effects of the Embodiments

In conclusion, in the immersion heat dissipation structure provided by the embodiments of the present disclosure, by virtue of “the surface having the at least two contact angles”, “the at least one part of the surface having the one of the at least two contact angles between the immersion cooling liquid that is greater than 90 degrees, and the at least another part of the surface having the another one of the at least two contact angles between the immersion cooling liquid that is from 0 degrees to 90 degrees”; “the immersion heat dissipation structure including the heat dissipation base, the at least one hydrophobic layer, and the at least one fin”, “the at least one fin and the at least one hydrophobic layer being correspondingly formed on the heat dissipation base”, “the at least one hydrophobic layer being formed on the area of the heat dissipation base other than the area where the at least one fin is arranged, and the surface of the at least one hydrophobic layer having the contact angle between the immersion cooling liquid that is greater than 90 degrees”; “the immersion heat dissipation structure including the heat dissipation base, the at least one hydrophilic layer, and the at least one fin”, “the at least one hydrophilic layer being formed on the at least one fin”, “the surface of the at least one hydrophilic layer having the contact angle between the immersion cooling liquid that is from 0 degrees to 90 degrees, the at least one hydrophilic layer and the at least one fin being made of two materials that are different from each other, and the at least one hydrophilic layer and the heat dissipation base being made of two materials that are different from each other”; “the immersion heat dissipation structure including the heat dissipation base, the at least one hydrophobic layer, the at least one hydrophilic layer, and the at least one fin”, “the at least one fin being formed on the heat dissipation base, the at least one hydrophilic layer being formed on the at least one fin, and the at least one hydrophobic layer being formed on the area of the heat dissipation base other than the area where the at least one fin is arranged”, and “the surface of the at least one hydrophobic layer having the contact angle between the immersion cooling liquid that is greater than 90 degrees, and the surface of the hydrophilic layer having the contact angle between the immersion cooling liquid that is from 0 degrees to 90 degrees”, the immersion heat dissipation structure provided by the embodiments of the present disclosure has both a hydrophilic property and a hydrophobic property, so that the main heat dissipation area has the high CHF and the low number of nucleation sites, while the auxiliary heat dissipation area has the high number of nucleation sites and the low CHF, thereby enhancing an effect of immersion heat dissipation.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An immersion heat dissipation structure having a macroscopic fin structure, comprising:
a surface having at least two contact angles;
wherein at least one part of the surface has one of the at least two contact angles between an immersion cooling liquid that is greater than 90 degrees, and at least another part of the surface has another one of the at least two contact angles between the immersion cooling liquid that is from 0 degrees to 90 degrees.

2. The immersion heat dissipation structure according to claim 1, wherein the macroscopic fin structure is a fin structure formed on the surface, and the fin structure has a height of at least 100 μm from the surface.

3. An immersion heat dissipation structure having a fin structure, comprising:
a heat dissipation base;
at least one hydrophobic layer; and
at least one fin;
wherein the at least one fin and the at least one hydrophobic layer are correspondingly formed on the heat dissipation base, and the at least one hydrophobic layer is formed on an area of the heat dissipation base other than an area where the at least one fin is arranged;
wherein a surface of the at least one hydrophobic layer has a contact angle between an immersion cooling liquid that is greater than 90 degrees.

4. The immersion heat dissipation structure according to claim 3, wherein the at least one hydrophobic layer is formed on the area of the heat dissipation base other than the area where the at least one fin is arranged by physical deposition, chemical deposition, or spraying, and the at least one fin is a pin fin, a plate fin, or a composite fin structure formed by a combination of the pin fin and the plate fin.

5. An immersion heat dissipation structure having a fin structure, comprising:
a heat dissipation base;
at least one hydrophilic layer; and
at least one fin;
wherein the at least one fin is formed on the heat dissipation base, and the at least one hydrophilic layer is formed on the at least one fin;
wherein a surface of the at least one hydrophilic layer has a contact angle between an immersion cooling liquid that is from 0 degrees to 90 degrees;
wherein the at least one hydrophilic layer and the at least one fin are made of two materials that are different from each other, and the at least one hydrophilic layer and the heat dissipation base are made of two materials that are different from each other.

6. The immersion heat dissipation structure according to claim 5, wherein the at least one hydrophilic layer is formed on the at least one fin by immersion plating, and the at least one fin is a pin fin, a plate fin, or a composite fin structure formed by a combination of the pin fin and the plate fin.

7. An immersion heat dissipation structure having a fin structure, comprising:
a heat dissipation base;
at least one hydrophobic layer;
at least one hydrophilic layer; and
at least one fin;
wherein the at least one fin is formed on the heat dissipation base, the at least one hydrophilic layer is formed on the at least one fin, and the at least one hydrophobic layer is formed on an area of the heat dissipation base other than an area where the at least one fin is arranged;
wherein a surface of the at least one hydrophobic layer has a contact angle between an immersion cooling liquid that is greater than 90 degrees, and a surface of the at least one hydrophilic layer has a contact angle between the immersion cooling liquid that is from 0 degrees to 90 degrees.

8. The immersion heat dissipation structure according to claim 7, wherein the at least one hydrophobic layer is formed on the area of the heat dissipation base other than the area where the at least one fin is arranged by physical deposition, chemical deposition, or spraying, and the at least one hydrophilic layer is formed on the at least one fin by immersion plating.

9. The immersion heat dissipation structure according to claim 7, wherein the at least one fin is a pin fin, a plate fin, or a composite fin structure formed by a combination of the pin fin and the plate fin.
